(19) United States
(12) Patent Application Publication
(10) Pub. No.: US 2026/0337469 A1
(43) Pub. Date: Oct. 29, 2026

(54) DECREASING MIGRATION OF MATERIALS FROM THERMAL MANAGEMENT AND/OR ELECTROMAGNETIC INTERFERENCE (EMI) MITIGATION MATERIALS

(71) Applicants: Laird Technologies, Inc., Chesterfield, MO (US); DuPont Specialty Products USA, LLC, Wilmington, DE (US); Rohm and Haas Electronic Materials LLC, Malborough, MA (US)

(72) Inventors: Jason L. Strader, Pepper Pike, OH (US); Michael S. Wladyka, Brocksville, OH (US); Ethan S. Simon, Abington, PA (US); Jeffrey Scott Meth, Landenberg, PA (US)

(21) Appl. No.: 19/176,739

(22) Filed: Apr. 11, 2025

Related U.S. Application Data
(63) Continuation of application No. PCT/US2023/035023, filed on Oct. 12, 2023.

(51) Int. Cl. C09K 5/14; C08K 3/34; C08K 7/24; C09D 5/18; C09D 5/24; C09D 7/40; C09D 7/61; C09D 183/04; C09J 7/38; C09J 9/02; C09J 11/04; H05K 9/00

(52) U.S. Cl. CPC C09K 5/14; C09D 5/18; C09D 5/24; C09D 7/61; C09D 7/70; C09D 183/04; C09J 7/38; C09J 9/02; C09J 11/04; H05K 9/0081; C08K 3/346; C08K 7/24; C08K 2201/001; C08K 2201/011; C09J 2203/326; C09J 2301/314; C09J 2301/408; C09J 2483/00

(57) ABSTRACT

The present disclosure relates to decreasing migration of materials from thermal management and/or electromagnetic interference (EMI) mitigation materials (e.g., thermal interface materials (TIMs), EMI absorbers, thermally-conductive EMI absorbers, electrically-conductive elastomers (ECEs), electrically-conductive composites, combinations thereof, etc.) and other polymer-inorganic composites used for other purposes. In exemplary embodiments, a method includes adding halloysite and/or hollow nanotubular inorganic structures and/or tubular inorganic nanomaterials to a composite in an amount sufficient for decreasing migration of materials from the composite. Also disclosed are exemplary embodiments of composites that include halloysite and/or hollow nanotubular inorganic structures and/or tubular inorganic nanomaterials in an amount sufficient for decreasing migration of materials from the composite.

### CROSS-REFERENCE TO RELATED APPLICATIONS

This application is a continuation of PCT Application No. PCT/US2023/035023 filed Oct. 12, 2023 (published as WO 2024/081360 published on Apr. 18, 2024) that claims priority to and the benefit of U.S. Provisional Patent Application No. 63/415,915 filed Oct. 13, 2022. The entire disclosures of the above applications are incorporated herein by reference.

### FIELD

The present disclosure relates to decreasing migration of materials from thermal management and/or electromagnetic interference (EMI) mitigation materials (e.g., thermal interface materials (TIMs), EMI absorbers, thermally-conductive EMI absorbers, electrically-conductive elastomers (ECEs), electrically-conductive composites, combinations thereof, etc.) and other polymer-inorganic composites used for other purposes.

### BACKGROUND

This section provides background information related to the present disclosure which is not necessarily prior art.

Electrical components, such as semiconductors, integrated circuit packages, transistors, etc., typically have pre-designed temperatures at which the electrical components optimally operate. Ideally, the pre-designed temperatures approximate the temperature of the surrounding air. But the operation of electrical components generates heat. If the heat is not removed, the electrical components may then operate at temperatures significantly higher than their normal or desirable operating temperature. Such excessive temperatures may adversely affect the operating characteristics of the electrical components and the operation of the associated device.

To avoid or at least reduce the adverse operating characteristics from the heat generation, the heat should be removed, for example, by conducting the heat from the operating electrical component to a heat sink. The heat sink may then be cooled by conventional convection and/or radiation techniques. During conduction, the heat may pass from the operating electrical component to the heat sink either by direct surface contact between the electrical component and heat sink and/or by contact of the electrical component and heat sink surfaces through an intermediate medium or thermal interface material (TIM). The thermal interface material may be used to fill the gap between thermal transfer surfaces, in order to increase thermal transfer efficiency as compared to having the gap filled with air, which is a relatively poor thermal conductor.

In addition, a common problem in the operation of electronic devices is the generation of electromagnetic radiation within the electronic circuitry of the equipment. Such radiation may result in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable.

A common solution to ameliorate the effects of EMI/RFI is through the use of shields capable of absorbing and/or reflecting and/or redirecting EMI energy. These shields are typically employed to localize EMI/RFI within its source, and to insulate other devices proximal to the EMI/RFI source. These shields may be composed of metal, polymer-inorganic composites, filled foams, foam materials wrapped or coated with absorbing and/or reflecting materials, and the like.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) broadly includes and refers to mitigating (or limiting) EMI and/or RFI, such as by absorbing, reflecting, blocking, and/or redirecting the energy or some combination thereof so that it no longer interferes, for example, for government compliance and/or for internal functionality of the electronic component system.

The above mitigation materials, if not comprised of metal, often consist of inorganic-polymer composites or metal-polymer composites. The concentration of the inorganic material, which is usually a particle, in the polymer matrices is often high, for the purpose of attaining the desired management of thermal and/or EMI issues. In some instances, the composites are used in applications where they are compressed between two portions of the device requiring management of thermal and/or EMI issues. This compression may occur during the assembly of a device or during cycles of compression and expansion during use of a device. As a result, the composites must be ‘soft’ so they can readily deflect and absorb the forces of compression, without transferring those forces to the device being protected with the associated risk of physical damage. As known to those skilled in the art, in some situations the methods used to prepare such soft composites lead to materials from which various organic species may migrate over time, particularly after repeated cycles of compression and expansion. These organic species may consist of polymers, monomers, additives used to form the composite or to enhance its performance during use, complexes of organic materials with inorganic materials, and the like. The term ‘oil bleed’ is commonly used within the industry to describe this phenomenon, and will be used in this document with the understanding that ‘oil’ refers to a range of primarily organic species and ‘bleed’ refers to the movement of materials from within the composites to a location, or locations, external to the composites.

### DRAWINGS

The drawings described herein are for illustrative purposes only of selected embodiments and not all possible implementations, and is not intended to limit the scope of the present disclosure.

FIG. 1 illustrates an exemplary embodiment in which a first thermal management and/or electromagnetic interference (EMI) mitigation material (e.g., a thermally-conductive EMI absorber, etc.) positioned between a board level shield and an integrated circuit or chip. FIG. 1 also illustrates a second thermal management and/or electromagnetic interference (EMI) mitigation material (e.g., a thermally-conductive pad, other thermal interface material, etc.) between a heat sink and the board level shield.

FIG. 2 illustrates example thermal gap fillers comprising ceramic filled silicone sheets to which may be added halloysite or other tubular nanomaterial/hollow nanotubular additives, such as imogolite, Saudi halloysite-like nanotubes and the like, in a sufficient amount (e.g., about 10 weight % or less, from about 5 to 10 weight %, from about 0.1 to 2 weight %, about 1 weight %, etc.) for decreasing migration of materials (e.g., silicone oil bleed, etc.) from the thermal gap filler according to exemplary embodiments of the present disclosure. In such exemplary embodiments, the thermal gap filler including halloysite additive may be configured to have a high thermal conductivity (e.g., about 4 W/mK or higher, etc.), low pressure versus deflection, and excellent surface wetting for low contact resistance. The thermal gap filler may also be compliant with minimal or at least reduced board and component stress during assembly. The thermal gap filler may be suitable for large tolerance applications. And the thermal gap filler may be in compliance with REACH and ROHS and/or have a UL flammability rating of UL V-0.

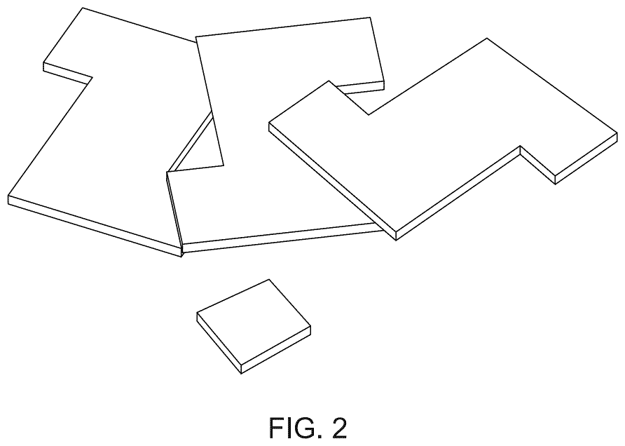

FIG. 3 includes example properties that a thermal gap filler comprising a ceramic filled silicone sheet including halloysite or other tubular nanomaterial/hollow nanotubular additive may have according to exemplary embodiments of the present disclosure. In other exemplary embodiments, the thermal gap filler may be configured differently, e.g., have one or more different properties than what is provided in FIG. 3 (e.g., thermal conductivity of greater than or less than 4 W/mK, etc.), etc.

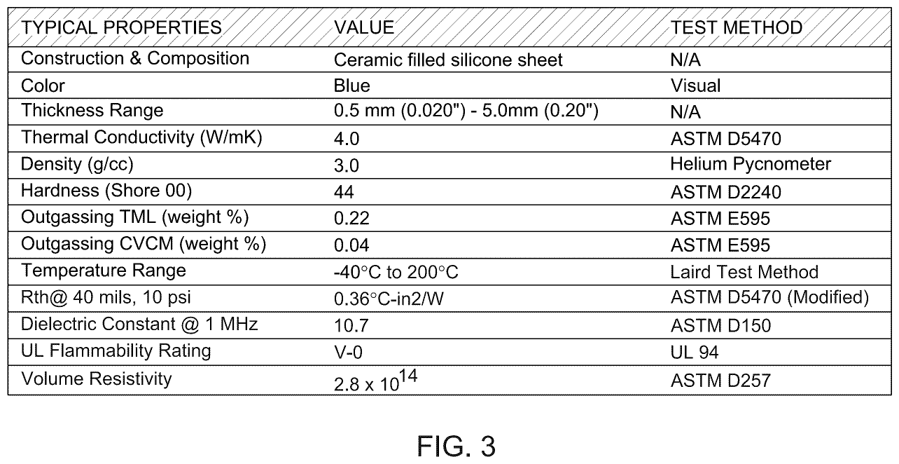

FIG. 4 is a line graph of deflection percentage versus pressure in pounds per square inch (PSI) that a thermal gap filler comprising a ceramic filled silicone sheet including halloysite or other tubular nanomaterial/hollow nanotubular additive may have according to exemplary embodiments of the present disclosure. The five thermal gap filler samples had different sheet thicknesses of 40 mils, 60 mils, 140 mils, 180 mils, and 200 mils. The ceramic filled silicone sheets included halloysite additive in a sufficient amount to decrease migration of materials (e.g., silicone oil bleed, etc.) from the thermal gap filler.

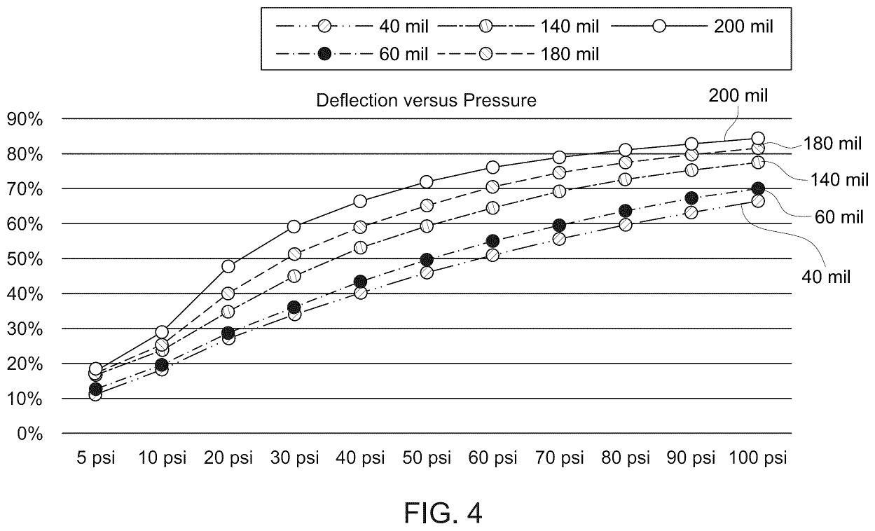

FIG. 5 is a line graph of thermal resistance in degrees Celsius square inch per Watt (C-in²/W) versus pressure in pounds per square inch (PSI) that a thermal gap filler comprising a ceramic filled silicone sheet including halloysite or other tubular nanomaterial/hollow nanotubular additive may have according to exemplary embodiments of the present disclosure. The four thermal gap filler samples had different sheet thicknesses of 40 mils, 60 mils, 80 mils, and 100 mils. The ceramic filled silicone sheets included halloysite additive in a sufficient amount sufficient to decrease migration of materials (e.g., silicone oil bleed, etc.) from the thermal gap filler.

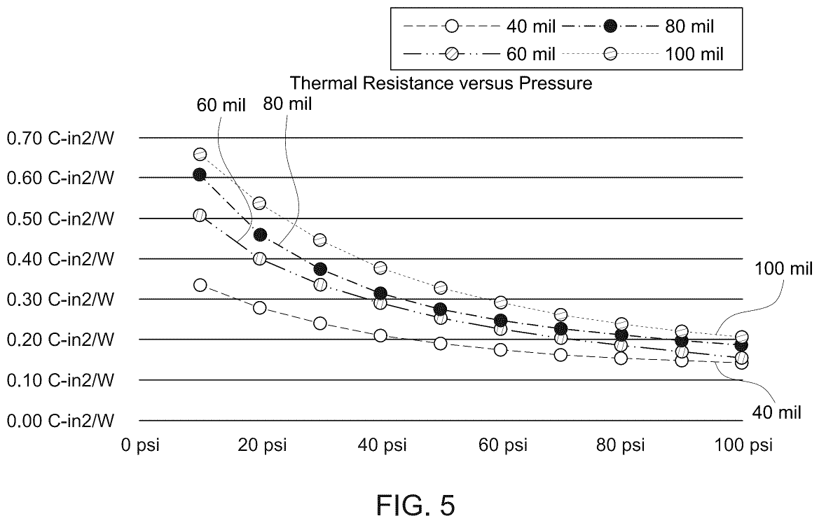

### DETAILED DESCRIPTION

Example embodiments will now be described more fully with reference to the accompanying drawings.

Disclosed herein are innovative methods for decreasing migration of materials (e.g., silicone oil bleed, etc.) from thermal management and/or electromagnetic interference (EMI) mitigation materials (e.g., thermal interface materials (TIMs), EMI absorbers, thermally-conductive EMI absorbers, electrically-conductive elastomers (ECEs), electrically-conductive composites, combinations thereof, etc.) and other polymer-inorganic composites used for other purposes.

Oil bleed is a concern for aesthetic reasons as well as due to the potential contamination of optics in electronic applications (e.g., optical transceivers, camera lenses, etc.). High speed signal lines may also be affected by oil bleed. Accordingly, it would be desirable to decrease and/or prevent migration of materials, such as silicone oil bleed, from polymer-inorganic composites used to mitigate thermal and/or EMI issues in devices. It would be further desirable to decrease migration of materials with minimal or insignificant change to other desirable properties of the composites.

It is, however, challenging to balance the preparation of a highly-loaded polymer composite for use as a thermal management and/or electromagnetic interference (EMI) mitigation material that has the ability to fulfill the desired mitigation requirements and other requirements while also readily deflecting under low levels of applied force. In these materials, oil bleed may result for multiple reasons. For example, conventional thermal management and/or electromagnetic interference (EMI) mitigation materials are commonly based on the use of silicone polymers. Silicone polymers typically contain a wide distribution of molecular weight (MW) polymers. It is commonly assumed that some of the polymer with low molecular weights are capable of migration in the matrix to such an extent that the migrated polymer materials become visibly apparent beyond the confines of the composite, thereby resulting in undesirable aesthetics. Other additives in the composite in addition to the silicone polymers, such as dispersing agents, stabilizing agents (e.g., UV stabilizers, thermal stabilizers, etc.) and the like, may also migrate. Composites that use polymers that are not based on silicone materials also contain species capable of migration, and face similar challenges are described above for representative silicone-based systems.

After recognizing the above, innovative methods were developed and/or disclose herein that solve the problem of how to prepare highly loaded polymer composites with the ability to readily deflect under low levels of applied force and without the undesirable migration or bleed of materials from the composite to surrounding areas. It was envisioned that tubular nanomaterial/hollow nanotubular additives, such as halloysite, imogolite, Saudi halloysite-like nanotubes and the like, could provide a way to reduce the migration of more mobile materials in a composite by preferentially adsorbing or reacting with those materials within the inner part of the nanotubes, without having unwanted interactions, such as hardening, with the bulk matrix of the composite. It is understood by those skilled in the art that these nanomaterials may be treated to modify their surfaces to provide compatibility with various matrices, and these variations are included in the definition of these materials.

As disclosed herein, exemplary embodiments include reducing migration of materials by using halloysite clay as an additive to thermal management and/or electromagnetic interference (EMI) mitigation materials (e.g., thermal interface materials, EMI absorbers, thermally-conductive EMI absorbers, electrically-conductive elastomers (ECEs), electrically-conductive composites, combinations thereof, etc.) and other polymer-inorganic composites used for other purposes. In exemplary embodiments, halloysite is added in a sufficient amount such that the resulting thermal management and/or electromagnetic interference (EMI) mitigation material has the following advantageous characteristic: reduced or undetectable bleed as compared to a thermal management and/or electromagnetic interference (EMI) mitigation material having the same formulation but without halloysite. In some instances, the addition of the clay may also provide a lower force required for deflection and may provide improved thixotropy.

For comparison purposes, oil absorbing materials were added to TIM pad formulations. The TIM pads with the oil absorbing materials were then compared to a TIM pad having the same formulation but without the oil absorbing materials. The different oil absorbents added to the TIM pad formulations included talcum powder, corn starch, alumina fiber, kaolin clay, and halloysite. It was observed that talcum powder, corn starch, alumina fiber, and kaolin clay absorbents did not perform as well as halloysite. In particular, halloysite resulted in significantly less oil bleed from the TIM pad while also improving or at least maintaining substantially the same deflection properties of the TIM pad. This observation is noteworthy in particular because kaolin clay and halloysite clay have similar chemical compositions: they differ in the physical structure of the clay particles. It was recognized that halloysite's unique nanotubular structure likely allows for absorption of free-moving polymer that would otherwise separate and migrate from the bulk material.

As compared to a TIM having the halloysite additive, a TIM having the same formulation without the halloysite additive has the tendency to bleed significantly more, which can result in aesthetic and performance issues in electronic applications. Though conventional methods exist to reduce bleed from a TIM, such conventional methods often have been found to significantly increase hardness such that the harder TIM is not able to readily deflect under low levels of applied force. Accordingly, exemplary embodiments are disclosed herein in which halloysite and/or other tubular nanomaterial/hollow nanotubular additive is added to a formulation for a thermal management and/or electromagnetic interference (EMI) mitigation material to reduce bleed and increase flexibility without detrimentally changing other desired properties of the thermal management and/or electromagnetic interference (EMI) mitigation material.

Experimental results have shown the positive impacts of adding 0.2 weight percent (wt %) and 0.5 wt % of halloysite to a formulation for a silicone based thermal gap filler pad. The addition of 0.5 wt % of halloysite to the formulation resulted in a silicone based thermal gap filler pad having an improved lower deflection force and reduced bleed to an undetectable amount. Analysis by microscopy indicated the presence of halloysite particles in the matrix. In contrast, the same improvements were not observed when 0.5 wt % of kaolin was added to the same formulation for the silicone based thermal gap filler pad.

By way of background, kaolin and halloysite have the same composition but in different structures. More specifically, halloysite comprises hollow nanotubular structures or tubular nanomaterials, whereas kaolin is plate-like. It is theorized that the tubular halloysite interacts with the bleed components more effectively than the plate-like kaolin, thereby creating a surprisingly effective outcome when using only a very small amount of the halloysite additive. The halloysite class of clays are nanotubular with most of the active hydroxyl groups on the inside of the nanotubes. It is hypothesized that the interior of the halloysite nanotube materials may capture lower molecular weight (MW) components in formulated products. The exterior of the halloysite tubular nanoparticles have a lower concentration of active groups, such that the amount of undesired crosslinking of the matrix polymer should be low.

Without limiting the scope or claims of the invention, it is believed that the ability of halloysite to reduce the migration of organic species stems from the interaction of those species with the aluminol groups within the nanotubes. As a result, this invention should have wide applicability to a wide range of formulated products used for the control of thermal and electromagnetic properties of materials, in which it is undesirable to have migration of organic species within the composite to locations external to the composite.

Accordingly, the present disclosure relates to decreasing migration of materials (e.g., oil bleed, etc.) from thermal management and/or electromagnetic interference (EMI) mitigation materials (e.g., thermal interface materials (TIMs), EMI absorbers, thermally-conductive EMI absorbers, electrically-conductive elastomers (ECEs), electrically-conductive composites, combinations thereof, etc.) and other polymer-inorganic composites used for other purposes. In exemplary embodiments, a composite includes a sufficient amount of halloysite and/or other hollow nanotubular inorganic structures or tubular inorganic nanomaterials, such as imogolite, Saudi halloysite-like nanotubes and the like, in an amount sufficient for decreasing migration of materials from the composite. The composite may comprise a thermal management and/or electromagnetic interference (EMI) mitigation material, such as a thermal interface material (TIM), EMI absorber, thermally-conductive EMI absorber, electrically-conductive elastomer (ECE), electrically-conductive composite, or combination thereof.

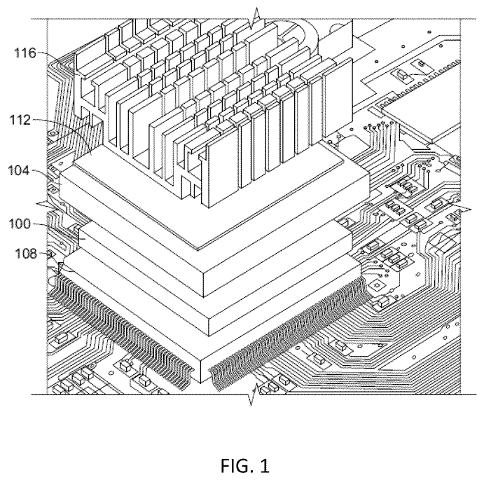

With reference to the figures, FIG. 1 illustrates first and second thermal management and/or electromagnetic interference (EMI) mitigation materials 100, 112 that include halloysite and/or hollow nanotubular inorganic structures or tubular inorganic nanomaterials (broadly, oil absorbent additive) in an amount sufficient to decrease migration of materials (e.g., silicone oil bleed, etc.) from the first and second thermal management and/or electromagnetic interference (EMI) mitigation materials 100, 112. As shown, the first thermal management and/or electromagnetic interference (EMI) mitigation material 100 is positioned between a board level shield 104 and an integrated circuit or chip 108. The second thermal management and/or electromagnetic interference (EMI) mitigation material 112 is positioned between a heat sink 116 and the board level shield 104.

The first thermal management and/or electromagnetic interference (EMI) mitigation material 100 may comprise a thermally-conductive EMI absorber operable as both a thermal interface material for establishing a thermally-conductive heat path between the integrated circuit 108 and the board level shield 104 and also an EMI absorber for suppressing radiating electromagnetic fields coupling between the integrated circuit 108 and the heat sink 116. Accordingly, first thermal management and/or electromagnetic interference (EMI) mitigation material 100 may therefore provide the combined performance of a thermal interface material and an EMI absorber in a space-saving dual-purpose, single-product solution.

As noted above, the first thermal management and/or electromagnetic interference (EMI) mitigation material 100 includes halloysite and/or other hollow nanotubular inorganic structures or tubular inorganic nanomaterials, such as imogolite, Saudi halloysite-like nanotubes and the like, in an amount sufficient to decrease migration of materials (e.g., silicone oil bleed, etc.) from the first thermal management and/or electromagnetic interference (EMI) mitigation material 100. The first thermal management and/or electromagnetic interference (EMI) mitigation material 100 also includes functional filler(s) (e.g., at least about 25 wt %, at least about 80 wt %, at least about 90 wt %, etc.) in the matrix or base material (e.g., a silicone-based polymer resin, a non-silicone-based polymer resin, etc.) for increasing thermal conductivity and/or for EMI absorption. Example functional fillers include carbon black, boron nitride, nickel cobalt, carbonyl iron, iron silicide, iron particles, iron-chrome compounds, silver, an alloy containing 85% iron, 9.5% silicon and 5.5% aluminum, an alloy containing about 20% iron and 80% nickel, ferrites, magnetic alloys, magnetic powders, magnetic flakes, magnetic particles, nickel-based alloys and powders, chrome alloys, oxide, copper, zinc oxide, alumina, graphite, ceramics, silicon carbide, manganese zinc, fiberglass, carbon nanotubes (e.g., single-walled carbon nanotubes, multi-walled carbon nanotubes, etc.), thermally-conductive materials including metal composites (e.g., gallium and gallium alloys, etc.) having melting points near or below room temperature, combinations thereof, etc.

In an exemplary embodiment, the first thermal management and/or electromagnetic interference (EMI) mitigation material 100 includes less than about 10 weight percent of matrix or base material, about 1 weight percent or less of halloysite nanotubes, and at least about 90 weight percent of functional filler. In other exemplary embodiments, the first thermal management and/or electromagnetic interference (EMI) mitigation material 100 may include different weight percentages of halloysite nanotubes or other hollow nanotubular inorganic structures or tubular inorganic nanomaterials, such as about 10 weight % or less, from about 5 to 10 weight %, from about 0.1 to 2 weight %, etc. The first thermal management and/or electromagnetic interference (EMI) mitigation material 100 may also include different weight percentages of matrix or base material (e.g., about 7 weight %, about 8 weight %, more than 10 weight %, etc.) and/or different weight percentages of functional filler (e.g., about 25 weight % or more, at least about 80 weight % but less than 90 weight %, more than 90 weight %, etc.).

In the example shown in FIG. 1, the first thermal management and/or electromagnetic interference (EMI) mitigation material 100 comprises a thermally-conductive EMI absorbing pad having a rectangular shape. Alternatively, the first thermal management and/or electromagnetic interference (EMI) mitigation material 100 may comprises a thermally-conductive EMI absorbing pad having a different shape, such as a different polygonal shape (e.g., pentagonal, triangular, etc.), etc.

The second thermal management and/or electromagnetic interference (EMI) mitigation material 112 may comprise a thermal interface material (TIM) that is operable for establishing a thermally-conductive heat path between the heat sink 116 and the board level shield 104. As noted above, the second thermal management and/or electromagnetic interference (EMI) mitigation material 112 includes halloysite and/or other hollow nanotubular inorganic structures or tubular inorganic nanomaterials, such as imogolite, Saudi halloysite-like nanotubes and the like, in an amount sufficient to decrease migration of materials (e.g., silicone oil bleed, etc.) from the second thermal management and/or electromagnetic interference (EMI) mitigation material 112. The second thermal management and/or electromagnetic interference (EMI) mitigation material 112 also includes thermally-conductive filler (e.g., about 25 wt % or more, at least about 80 wt %, at least about 90 wt %, etc.) in the matrix or base material (e.g., a silicone-based polymer resin, a non-silicone-based polymer resin, etc.). The thermally-conductive filler may comprise one or more of alumina, aluminum, zinc oxide, boron nitride, silicon nitride, aluminum nitride, iron, metallic oxides, graphite, silver, copper, ceramic, thermally-conductive materials including metal composites (e.g., gallium and gallium alloys, etc.) having melting points near or below room temperature, combinations thereof.

By way of example only, the second thermal management and/or electromagnetic interference (EMI) mitigation material 112 may include less than about 10 weight percent of matrix or base material, about 1 weight percent or less of halloysite additive, and at least about 90 weight percent of thermally-conductive filler. In other exemplary embodiments, the second thermal management and/or electromagnetic interference (EMI) mitigation material 112 may include different weight percentages of halloysite nanotubes or other hollow nanotubular inorganic structures or tubular inorganic nanomaterials, such as about 10 weight % or less, from about 5 to 10 weight %, from about 0.1 to 2 weight %, etc. The second thermal management and/or electromagnetic interference (EMI) mitigation material 112 may also include different weight percentages of matrix or base material (e.g., about 7 weight %, about 8 weight %, more than 10 weight %, etc.) and/or different weight percentages of functional filler (e.g., about 25 weight % or more, at least about 80 weight % but less than 90 weight %, more than 90 weight %, etc.).

In the example shown in FIG. 1, the second thermal management and/or electromagnetic interference (EMI) mitigation material 112 comprises a thermally-conductive pad having a rectangular shape. Alternatively, the second thermal management and/or electromagnetic interference (EMI) mitigation material 112 may comprises a thermally-conductive pad having a different shape, such as a different polygonal shape (e.g., pentagonal, triangular, etc.). In alternative embodiments, the second thermal management and/or electromagnetic interference (EMI) mitigation material 112 may comprise a dispensable material, a thermal grease, a bulk putty, a phase change TIM, etc.

Disclosed herein are methods for decreasing migration of materials (e.g., silicone oil bleed, etc.) from composites, such as thermal management and/or electromagnetic interference (EMI) mitigation materials (e.g., thermal interface materials (TIMs), EMI absorbers, thermally-conductive EMI absorbers, electrically-conductive elastomers (ECEs), electrically-conductive composites, combinations thereof, etc.) and other polymer-inorganic composites used for other purposes.

In exemplary embodiments, a method comprises adding halloysite, hollow nanotubular inorganic structures, and/or tubular inorganic nanomaterials to a composite in an amount sufficient for decreasing migration of materials from the composite. In such exemplary embodiments, the hollow inorganic nanotubular structures and/or tubular inorganic nanomaterials added to the composite may comprise halloysite and/or other hollow inorganic nanotubular structures/tubular inorganic nanomaterials, such as imogolite, Saudi halloysite-like nanotubes and the like.

In exemplary embodiments, the composite is a polydimethylsiloxane (PDMS)-based polymer-inorganic composite. And the method includes adding halloysite, hollow nanotubular inorganic structures, and/or tubular inorganic nanomaterials to the polydimethylsiloxane (PDMS)-based polymer-inorganic composite.

In exemplary embodiments, the composite is a polymer-inorganic composite substantially free of siloxane polymers. And the method includes adding halloysite, hollow nanotubular inorganic structures, and/or tubular inorganic nanomaterials to the polymer-inorganic composite that is substantially free of siloxane polymers.

In exemplary embodiments, the method further comprises adding one or more of the following to the composite: thermally-conductive filler(s), electrically-conductive filler(s), electromagnetic wave absorbing filler(s), dielectric absorbing filler(s), and filler(s) that has two or more properties of being thermally conductive, electrically conductive, dielectric absorbing, and electromagnetic wave absorbing. For example, the method may include adding one or more of the following to the composite: carbon black, boron nitride, nickel cobalt, carbonyl iron, iron silicide, iron particles, iron-chrome compounds, silver, an alloy containing 85% iron, 9.5% silicon and 5.5% aluminum, an alloy containing about 20% iron and 80% nickel, ferrites, magnetic alloys, magnetic powders, magnetic flakes, magnetic particles, nickel-based alloys and powders, chrome alloys, oxide, copper, zinc oxide, alumina, graphite, ceramics, silicon carbide, manganese zinc, fiberglass, carbon nanotubes (e.g., single-walled carbon nanotubes, multi-walled carbon nanotubes, etc.), thermally-conductive materials including metal composites (e.g., gallium and gallium alloys, etc.) having melting points near or below room temperature, combinations thereof, etc.

In exemplary embodiments, the method includes adding halloysite, hollow nanotubular inorganic structures, and/or tubular inorganic nanomaterials in an amount sufficient for: absorbing and/or binding uncross-linked polymer of the composite that may otherwise migrate from the composite; and/or absorbing lightly crosslinked and/or low molecular weight crosslinked polymer and other fluid materials and additives that may otherwise migrate from the composite.

In exemplary embodiments, the method includes adding halloysite, hollow nanotubular inorganic structures, and/or tubular inorganic nanomaterials to the composite in an amount sufficient to reduce silicone oil bleed from the composite thereby enabling the composite to be usable substantially or entirely without silicone migration beyond confines of the composite and to readily deflect under low levels of applied force.

In exemplary embodiments, the method includes adding halloysite, hollow nanotubular inorganic structures, and/or tubular inorganic nanomaterials to the composite such that the composite includes up to about 10 weight percent of halloysite, hollow nanotubular inorganic structures, and/or tubular inorganic nanomaterials. For example, the composite may include about 10 weight percent or less of halloysite, hollow nanotubular inorganic structures, and/or tubular inorganic nanomaterials. Or, for example, the composite may include from about 5 to 10 weight percent of halloysite, hollow nanotubular inorganic structures, and/or tubular inorganic nanomaterials. As a further example, the composite may include from about 0.1 to 2 weight percent of halloysite, hollow nanotubular inorganic structures, and/or tubular inorganic nanomaterials. As yet another example, the composite may include about 1 weight percent of halloysite, hollow nanotubular inorganic structures, and/or tubular inorganic nanomaterials.

In exemplary embodiments, the composite is a thermal management and/or electromagnetic interference (EMI) mitigation material usable for managing thermal and/or electromagnetic properties of a device or system.

In exemplary embodiments, the composite is a thermal interface material, an EMI absorber, a thermally-conductive absorber, an electrically-conductive elastomer, an electrically-conductive composite, or a combination of two or more thereof. For example, the composite may comprise a thermal interface material that is a thermally-conductive pad, thermally-conductive gap filler, dispensable material, thermal grease, bulk putty, or a phase change TIM.

In exemplary embodiments, the method includes using the composite for managing thermal and/or electromagnetic properties of a device or system.

In exemplary embodiments, the method includes dispensing the composite onto a surface of a device for managing thermal and/or electromagnetic properties of the device or a system including the device.

In exemplary embodiments, the method includes removing a release liner from the composite, and positioning the composite onto a surface of the device for managing thermal and/or electromagnetic properties of the device or a system including the device.

In exemplary embodiments, a composite comprises halloysite, hollow nanotubular inorganic structures, and/or tubular inorganic nanomaterials in an amount sufficient for decreasing migration of materials from the composite. In such exemplary embodiments, hollow nanotubular inorganic structures and/or tubular inorganic nanomaterials hollow inorganic may comprise halloysite and/or other hollow inorganic nanotubular structures/tubular inorganic nanomaterials, such as imogolite, Saudi halloysite-like nanotubes and the like.

In exemplary embodiments, the composite is a polydimethylsiloxane (PDMS)-based polymer-inorganic composite.

In exemplary embodiments, the composite is a polymer-inorganic composite substantially free of siloxane polymers.

In exemplary embodiments, the composite further comprises one or more of: thermally-conductive filler(s), electrically-conductive filler(s), electromagnetic wave absorbing filler(s), dielectric absorbing filler(s), and filler(s) that has two or more properties of being thermally conductive, electrically conductive, dielectric absorbing, and electromagnetic wave absorbing. For example, the composite may include one or more: carbon black, boron nitride, nickel cobalt, carbonyl iron, iron silicide, iron particles, iron-chrome compounds, silver, an alloy containing 85% iron, 9.5% silicon and 5.5% aluminum, an alloy containing about 20% iron and 80% nickel, ferrites, magnetic alloys, magnetic powders, magnetic flakes, magnetic particles, nickel-based alloys and powders, chrome alloys, oxide, copper, zinc oxide, alumina, graphite, ceramics, silicon carbide, manganese zinc, fiberglass, carbon nanotubes (e.g., single-walled carbon nanotubes, multi-walled carbon nanotubes, etc.), thermally-conductive materials including metal composites (e.g., gallium and gallium alloys, etc.) having melting points near or below room temperature, combinations thereof, etc.

In exemplary embodiments, the halloysite, hollow nanotubular inorganic structures, and/or tubular inorganic nanomaterials are in an amount sufficient for: absorbing and/or binding uncross-linked polymer of the composite that may otherwise migrate from the composite; and/or absorbing lightly crosslinked and/or low molecular weight crosslinked polymer and other fluid materials and additives that may otherwise migrate from the composite.

In exemplary embodiments, the halloysite, hollow nanotubular inorganic structures, and/or tubular inorganic nanomaterials are in an amount sufficient to reduce silicone oil bleed from the composite thereby enabling the composite to be usable substantially or entirely without silicone migration beyond confines of the composite and to readily deflect under low levels of applied force.

In exemplary embodiments, the composite includes up to about 10 weight percent of halloysite, hollow nanotubular inorganic structures, and/or tubular inorganic nanomaterials. For example, the composite may include about 10 weight percent or less of halloysite, hollow nanotubular inorganic structures, and/or tubular inorganic nanomaterials. Or, for example, the composite may include from about 5 to 10 weight percent of halloysite, hollow nanotubular inorganic structures, and/or tubular inorganic nanomaterials. As a further example, the composite may include from about 0.1 to 2weight percent of halloysite, hollow nanotubular inorganic structures, and/or tubular inorganic nanomaterials. As yet another example, the composite may include about 1 weight percent of halloysite, hollow nanotubular inorganic structures, and/or tubular inorganic nanomaterials.

By way of further example, the composite may include different weight percentages of the matrix or base material, such as about 7 weight %, about 8 weight %, about 10 weight %, more than 10 weight %, etc. Also by way of example, the composite may include different weight percentages of filler, such as about 25 weight % or more, at least about 80 weight % but less than 90 weight %, more than 90 weight %, etc.

In exemplary embodiments, the composite is electrically conductive or electrically insulating, thermally-conductive or thermally insulating, EMI absorbing, or a combination of any or all of the previously mentioned properties.

In exemplary embodiments, the composite is configured to be usable for managing thermal and/or electromagnetic properties of a device or system.

In exemplary embodiments, the composite is a thermal management and/or electromagnetic interference (EMI) mitigation material.

In exemplary embodiments, the composite is a thermal interface material, an EMI absorber, a thermally-conductive absorber, an electrically-conductive elastomer, an electrically-conductive composite, or a combination of two or more thereof.

In exemplary embodiments, a device or system comprises a composite as disclosed herein, which composite is used for managing thermal and/or electromagnetic properties of the device or system.

In exemplary embodiments, the composite is EMI absorbing and/or electrically conductive, such that the composite is usable for mitigating and/or managing EMI within an electronic device.

In an exemplary embodiment, an electronic device includes a heat source and a composite as disclosed herein. The composite is positioned relative to the heat source for establishing at least a portion of a thermally-conductive heat path from the heat source through the composite. The halloysite, hollow nanotubular inorganic structures, and/or tubular inorganic nanomaterials in the composite decrease migration of materials (e.g., silicone oil bleed, etc.) from the composite onto the heat source. The composite may also be configured to be EMI absorbing and/or electrically conductive, such that the composite is also operable for mitigating and/or managing EMI within the electronic device.

In an exemplary embodiment, an electronic device includes a heat source, a heat removal/dissipation structure, and a composite as disclosed herein. The composite is positioned relative to the heat source and the heat removal/dissipation structure for establishing at least a portion of a thermally-conductive heat path between the heat source and the heat removal/dissipation structure. The halloysite, hollow nanotubular inorganic structures, and/or tubular inorganic nanomaterials in the composite decrease migration of materials (e.g., silicone oil bleed, etc.) from the composite onto the heat source and the heat removal/dissipation structure. The composite may also be configured to be EMI absorbing and/or electrically conductive, such that the composite is also operable for mitigating and/or managing EMI within the electronic device.

In an exemplary embodiment, an electronic device includes a heat source, a board level shield, and a composite as disclosed herein. The composite is positioned relative to the heat source and the board level shield for establishing at least a portion of a thermally-conductive heat path between the heat source and the board level shield. The halloysite, hollow nanotubular inorganic structures, and/or tubular inorganic nanomaterials in the composite decrease migration of materials (e.g., silicone oil bleed, etc.) from the composite onto the heat source and the board level shield. The composite may also be configured to be EMI absorbing and/or electrically conductive, such that the composite is also operable for mitigating and/or managing EMI within the electronic device.

In an exemplary embodiment, an electronic device includes a heat source, a board level shield, a heat removal/dissipation structure, and first and second composites as disclosed herein. The first composite is positioned relative to the heat source and the board level shield for establishing at least a portion of a first thermally-conductive heat path between the heat source and the board level shield. The halloysite, hollow nanotubular inorganic structures, and/or tubular inorganic nanomaterials in the first composite decrease migration of materials (e.g., silicone oil bleed, etc.) from the first composite onto the heat source and the board level shield. The second composite is positioned relative to the board level shield and the heat removal/dissipation structure for establishing at least a portion of a second thermally-conductive heat path between the board level shield and the heat removal/dissipation structure. The halloysite, hollow nanotubular inorganic structures, and/or tubular inorganic nanomaterials in the second composite decrease migration of materials (e.g., silicone oil bleed, etc.) from the second composite onto the board level shield and the heat removal/dissipation structure. The first and/or second composites may also be configured to be EMI absorbing and/or electrically conductive, such that the first and/or second composites are also operable for mitigating and/or managing EMI within the electronic device.

In an exemplary embodiment, an electronic device includes an integrated circuit, a board level shield, a heat sink, and first and second composites as disclosed herein. The first composite is positioned relative to the integrated circuit and the board level shield for establishing at least a portion of a first thermally-conductive heat path between the integrated circuit and the board level shield. The halloysite, hollow nanotubular inorganic structures, and/or tubular inorganic nanomaterials in the first composite decrease migration of materials (e.g., silicone oil bleed, etc.) from the first composite onto the integrated circuit and the board level shield. The second composite is positioned relative to the board level shield and the heat sink for establishing at least a portion of a second thermally-conductive heat path between the board level shield and the heat sink. The halloysite, hollow nanotubular inorganic structures, and/or tubular inorganic nanomaterials in the second composite decrease migration of materials (e.g., silicone oil bleed, etc.) from the second composite onto the board level shield and the heat sink. The first and/or second composites may also be configured to be EMI absorbing and/or electrically conductive, such that the first and/or second composites are also operable for mitigating and/or managing EMI within the electronic device.

In addition to halloysite and/or other tubular nanomaterial/hollow nanotubular additive(s), such as imogolite, Saudi halloysite-like nanotubes and the like, for reducing migration of materials (e.g., silicone oil bleed, etc.), one or more other suitable fillers and/or additives may also be added to a bulk material for a thermal management and/or EMI mitigation material or other polymer-inorganic composite used for other purposes. For example, one or more of the following may also be added: functional nanoparticles, electrically-conductive fillers, thermally-conductive fillers, EMI or microwave absorbing fillers, magnetic fillers, coated fillers, catalyst for controlling curing, coupling agent for increasing filler loading, pigment or dye for adding color, plasticizers, process aids, flame retardants, extenders, tackifying agents, antioxidants, ultraviolet (UV) stabilizers, thermal stabilizers, combinations thereof, etc. Filler(s) may be added and mixed into a bulk material including the matrix or base material and the thereby provide a mixture of the filler(s), halloysite additive, and matrix or base material. Example fillers include carbon black, boron nitride, nickel cobalt, carbonyl iron, iron silicide, iron particles, iron-chrome compounds, silver, an alloy containing 85% iron, 9.5% silicon and 5.5% aluminum, an alloy containing about 20% iron and 80% nickel, ferrites, magnetic alloys, magnetic powders, magnetic flakes, magnetic particles, nickel-based alloys and powders, chrome alloys, oxide, copper, zinc oxide, alumina, graphite, ceramics, silicon carbide, manganese zinc, fiberglass, carbon nanotubes (e.g., single-walled carbon nanotubes, multi-walled carbon nanotubes, and/or carbon nanostructures, etc.), thermally-conductive materials including metal composites (e.g., gallium and gallium alloys, etc.) having melting points near or below room temperature, combinations thereof, etc. The filler(s) may comprise one or more of granules, spheroids, microspheres, ellipsoids, irregular spheroids, strands, flakes, powder, nanotubes, and/or a combination of any or all of these shapes. In addition, exemplary embodiments may also include different grades (e.g., different sizes, different purities, different shapes, etc.) of the same (or different) fillers.

In exemplary embodiments in which the composite includes halloysite nanotubes, the halloysite nanotubes may comprise aluminosilicate clay hollow nanotubular structures having a chemical composition of Al₂Si₂O₅(OH)₄·nH₂O. The aluminosilicate clay hollow nanotubular structures may have a wall thickness of about 10 to 15 atomic aluminosilicate sheets, an outer diameter of about 50 to 70 nanometers (nm), an inner diameter of about 10 to 15 nm, and a length of 0.5 to 10 micrometers (μm).

In exemplary embodiments, the composite is compliant with ROHS Directive 2011/65/EU and (EU) 2015/863 ad/or compliant with REACH as containing less than 0.1% by weight of substances on the REACH/SVHC candidate list (Jun. 25, 2020). In exemplary embodiments, the composite includes no more than a regulated threshold of 0.01% by weight of cadmium, no more than a regulated threshold of 0.1% by weight of Lead, no more than a regulated threshold of 0.1% by weight of mercury, no more than a regulated threshold of 0.1% by weight of hexavalent chromium, no more than a regulated threshold of 0.1% by weight of flame retardants PBB and PBDE including pentabromodiphenyl ether (CAS-No. 32534-81-9), octabromodiphenyl ether (CAS-No. 32536-52-0) and decabromodiphenyl ether (CAS-No. 1163-19-5), no more than a regulated threshold of 0.1% by weight of Bis(2-ethylhexyl) phthalate (DEHP) (CAS-No. 117-81-7), no more than a regulated threshold of 0.1% by weight of butyl benzyl phthalate (BBP) (CAS-No. 85-68-7), no more than a regulated threshold of 0.1% by weight of dibutyl phthalate (DBP) (CAS-No. 84-74-2), and no more than a regulated threshold of 0.1% by weight diisobutyl phthalate (DIBP) (CAS-No. 84-69-5).

Exemplary embodiments of the thermal management and/or EMI mitigation materials disclosed herein may be used in a wide range of industries (e.g., automotive, consumer, industrial, telecom/datacom, aerospace/defense, etc.) and wide range of applications (e.g., automotive electronics, automotive advanced driver-assistance systems (ADAS), automotive powertrain/electronic control units (ECUs), automotive infotainment, routers, wireless infrastructure, drones/satellites, gaming systems, smart home devices, notebooks/tablets/portable devices, etc.).

In exemplary embodiments, a composite including halloysite and/or other hollow nanotubular inorganic structures or tubular inorganic nanomaterials, such as imogolite, Saudi halloysite-like nanotubes and the like, is provided as a thermal gap filler sheet having a thickness within a range from about 0.1 mm to about 10 mm. The thermal gap filler sheet may have a thermal conductivity of at least about 4 Watts per meter per Kelvin (W/mK). The thermal gap filler sheet may be dielectric and not electrically conductive. The thermal gap filler sheet may have a hardness of about 44 Shore 00 or less at 3 seconds. The numerical values provided in this paragraph are only examples as other embodiments may be configured differently, such as having a different thickness, a hardness more than about 44 Shore 00 or less at 3 seconds, and/or a thermal conductivity higher than or less than 4 W/mK, etc. In other exemplary embodiments, a composite may have a hardness within a determined range (e.g., +/−10, etc.) of about 80 Shore 00 (e.g., about 80 Shore 00 at 3 seconds, about 70 Shore 00 at 3 seconds, about 60 Shore 00 at 3 seconds, etc.). In yet other exemplary embodiments, a composite (e.g., an EMI absorber, etc.) may have a hardness in the shore A range.

In exemplary embodiments, the composite including halloysite and/or other hollow nanotubular inorganic structures or tubular inorganic nanomaterials, such as imogolite, Saudi halloysite-like nanotubes and the like, is a thermal interface material (TIM), such as a thermally-conductive pad, thermally-conductive gap filler, dispensable material, thermal grease, bulk putty, phase change TIM, etc. In exemplary embodiments, the composite including halloysite nanotubes or other hollow nanotubular inorganic structures or tubular inorganic nanomaterials is a thermal management and/or EMI mitigation material having a relatively high thermal conductivity (e.g., 1 W/mK (watts per meter per Kelvin), 1.1 W/mK, 1.2 W/mK, 2.8 W/mK, 3 W/mK, 3.1 W/mK, 3.8 W/mK, 4 W/mK, 4.7 W/mK, 5 W/mK, 5.4 W/mK, 6 W/mK, 8 W/mK, etc.) depending on the particular materials used to make the thermal management and/or EMI mitigation material and loading percentage of the thermally conductive filler, if any. These thermal conductivities are only examples as other embodiments may include a thermal management and/or EMI mitigation material with a thermal conductivity higher than 8 W/mK, less than 1 W/mK (e.g., at least about 0.3 W/mK, etc.), or a value within a range from 1 W/mK to 8 W/mK.

In exemplary embodiments, a thermal management and/or EMI mitigation material (e.g., a thermal interface material, thermally-conductive EMI absorber, etc.) including halloysite and/or other hollow nanotubular inorganic structures or tubular inorganic nanomaterials may be used to define or provide part of a thermally-conductive heat path from a heat source to a heat removal/dissipation structure or component. The thermal management and/or EMI mitigation material may be used, for example, to help conduct thermal energy (e.g., heat, etc.) away from a heat source of an electronic device. The thermal management and/or EMI mitigation material may be positionable generally between (e.g., directly against in physical contact with, in thermal contact with, etc.) a heat source and a heat removal/dissipation structure or component to establish a thermal joint, interface, pathway, or thermally-conductive heat path along which heat may be transferred (e.g., conducted) from the heat source to the heat removal/dissipation structure or component. During operation, the thermal management and/or EMI mitigation material may function to allow transfer of heat (e.g., to conduct heat, etc.) from the heat source along the thermally-conductive path to the heat removal/dissipation structure or component. In exemplary embodiments, the thermal management and/or EMI mitigation material may also be operable for mitigating EMI (e.g., absorbing EMI, etc.) incident upon the thermal management and/or EMI mitigation material.

Example embodiments disclosed herein may be used with a wide range of heat sources, electronic devices, and/or heat removal/dissipation structures or components (e.g., a heat spreader, a heat sink, a heat pipe, a vapor chamber, a device exterior case, housing, or chassis, etc.). For example, a heat source may comprise one or more heat generating components or devices, such as a high-power integrated circuit (IC), optical transceiver, 5G infrastructure devices (e.g., base stations, small cells, smart poles, etc.), memory in video cards, set top boxes, televisions, gaming systems, automotive electronics used for autonomous driving (ADAS) (e.g., radars, multi domain controllers, cameras, etc.), a CPU, die within underfill, semiconductor device, flip chip device, graphics processing unit (GPU), digital signal processor (DSP), multiprocessor system, integrated circuit (IC), multi-core processor, etc.). Generally, a heat source may comprise any component or device that has a higher temperature than the thermal management and/or EMI mitigation material or otherwise provides or transfers heat to the thermal management and/or EMI mitigation material regardless of whether the heat is generated by the heat source or merely transferred through or via the heat source. Accordingly, aspects of the present disclosure should not be limited to use with any single type of heat source, electronic device, heat removal/dissipation structure, etc.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. For example, when permissive phrases, such as “may comprise”, “may include”, and the like, are used herein, at least one embodiment comprises or includes the feature(s). As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances. Or for example, the term “about” as used herein when modifying a quantity of an ingredient or reactant of the invention or employed refers to variation in the numerical quantity that can happen through typical measuring and handling procedures used, for example, when making concentrates or solutions in the real world through inadvertent error in these procedures; through differences in the manufacture, source, or purity of the ingredients employed to make the compositions or carry out the methods; and the like. The term “about” also encompasses amounts that differ due to different equilibrium conditions for a composition resulting from a particular initial mixture. Whether or not modified by the term “about”, equivalents to the quantities are included.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method comprising adding halloysite, hollow nanotubular inorganic structures, and/or tubular inorganic nanomaterials to a composite in an amount sufficient for decreasing migration of materials from the composite.

2. The method of claim 1, wherein the method includes adding the halloysite to the composite in the amount sufficient for decreasing migration of materials from the composite.

3. The method of claim 1, wherein the method includes adding the hollow nanotubular inorganic structures to the composite in the amount sufficient for decreasing migration of materials from the composite.

4. The method of claim 1, wherein the method includes adding the tubular inorganic nanomaterials to the composite in the amount sufficient for decreasing migration of materials from the composite.

5. The method of claim 1, wherein:
the halloysite, hollow nanotubular inorganic structures, and/or tubular inorganic nanomaterials comprise hollow nanotubular halloysite structures; and
the method includes adding the hollow nanotubular halloysite structures to the composite in the amount sufficient for decreasing migration of materials from the composite.

6. The method of claim 1, wherein:
the halloysite, hollow nanotubular inorganic structures, and/or tubular inorganic nanomaterials comprise tubular halloysite nanomaterials; and
the method includes adding the tubular halloysite nanomaterials to the composite in the amount sufficient for decreasing migration of materials from the composite.

7. The method of claim 1, wherein the halloysite, hollow nanotubular inorganic structures, and/or tubular inorganic nanomaterials are in an amount sufficient to reduce silicone oil bleed from the composite thereby enabling the composite to be usable substantially or entirely without silicone migration beyond confines of the composite and to readily deflect under low levels of applied force.

8. The method of claim 1, wherein:
the composite is a polydimethylsiloxane (PDMS)-based polymer-inorganic composite or a polymer-inorganic composite substantially free of siloxane polymers; and/or
the composite includes up to about 10 weight percent of the halloysite, hollow nanotubular inorganic structures, and/or tubular inorganic nanomaterials.

9. The method of claim 1, wherein the halloysite, hollow nanotubular inorganic structures, and/or tubular inorganic nanomaterials are in an amount sufficient for absorbing and/or binding uncross-linked polymer of the composite that may otherwise migrate from the composite.

10. The method of claim 1, wherein the halloysite, hollow nanotubular inorganic structures, and/or tubular inorganic nanomaterials are in an amount sufficient for absorbing lightly crosslinked and/or low molecular weight crosslinked polymer and other fluid materials and additives that may otherwise migrate from the composite.

11. The method of claim 1, wherein the method further comprises adding one or more of the following to the composite: thermally-conductive filler(s), electrically-conductive filler(s), electromagnetic wave absorbing filler(s), dielectric absorbing filler(s), and filler(s) that has two or more properties of being thermally conductive, electrically conductive, dielectric absorbing, and electromagnetic wave absorbing such that:
the composite is a thermal management and/or electromagnetic interference (EMI) mitigation material configured to be usable for managing thermal and/or electromagnetic properties of a device or system; and/or
the composite is a thermal interface material, an EMI absorber, a thermally-conductive absorber, an electrically-conductive elastomer, an electrically-conductive composite, or a combination of two or more thereof.

12. A composite comprising halloysite, hollow nanotubular inorganic structures, and/or tubular inorganic nanomaterials in an amount sufficient for decreasing migration of materials from the composite.

13. The composite of claim 12, wherein:
the halloysite, hollow nanotubular inorganic structures, and/or tubular inorganic nanomaterials comprise the halloysite; and
the composite comprises the halloysite in the amount sufficient for decreasing migration of materials from the composite.

14. The composite of claim 12, wherein:
the halloysite, hollow nanotubular inorganic structures, and/or tubular inorganic nanomaterials comprise the hollow nanotubular inorganic structures; and
the composite comprises the hollow nanotubular inorganic structures in the amount sufficient for decreasing migration of materials from the composite.

15. The composite of claim 12, wherein:
the halloysite, hollow nanotubular inorganic structures, and/or tubular inorganic nanomaterials comprise the tubular inorganic nanomaterials; and
the composite comprises the tubular inorganic nanomaterials in the amount sufficient for decreasing migration of materials from the composite.

16. The composite of claim 12, wherein:
the halloysite, hollow nanotubular inorganic structures, and/or tubular inorganic nanomaterials comprise hollow nanotubular halloysite structures; and
the composite comprises the hollow nanotubular halloysite structures in the amount sufficient for decreasing migration of materials from the composite.

17. The composite of claim 12, wherein:
the halloysite, hollow nanotubular inorganic structures, and/or tubular inorganic nanomaterials comprise tubular halloysite nanomaterials; and
the composite comprises the tubular halloysite nanomaterials in the amount sufficient for decreasing migration of materials from the composite.

18. The composite of claim 12, wherein the halloysite, hollow nanotubular inorganic structures, and/or tubular inorganic nanomaterials are in an amount sufficient to reduce silicone oil bleed from the composite thereby enabling the composite to be usable substantially or entirely without silicone migration beyond confines of the composite and to readily deflect under low levels of applied force.

19. The composite of claim 12, wherein:
the composite is a polydimethylsiloxane (PDMS)-based polymer-inorganic composite or a polymer-inorganic composite substantially free of siloxane polymers; and/or
the composite includes up to about 10 weight percent of the halloysite, hollow nanotubular inorganic structures, and/or tubular inorganic nanomaterials.

20. The composite of claim 12, wherein the halloysite, hollow nanotubular inorganic structures, and/or tubular inorganic nanomaterials are in an amount sufficient for absorbing and/or binding uncross-linked polymer of the composite that may otherwise migrate from the composite.

21. The composite of claim 12, wherein the halloysite, hollow nanotubular inorganic structures, and/or tubular inorganic nanomaterials are in an amount sufficient for absorbing lightly crosslinked and/or low molecular weight crosslinked polymer and other fluid materials and additives that may otherwise migrate from the composite.

22. The composite of claim 12, wherein the composite further comprises one or more thermally-conductive filler(s), electrically-conductive filler(s), electromagnetic wave absorbing filler(s), dielectric absorbing filler(s), and filler(s) that has two or more properties of being thermally conductive, electrically conductive, dielectric absorbing, and electromagnetic wave absorbing such that:
the composite is a thermal management and/or electromagnetic interference (EMI) mitigation material configured to be usable for managing thermal and/or electromagnetic properties of a device or system; and/or
the composite is a thermal interface material, an EMI absorber, a thermally-conductive absorber, an electrically-conductive elastomer, an electrically-conductive composite, or a combination of two or more thereof.

23. A method comprising using a composite for managing thermal and/or electromagnetic properties of a device or system, the composite comprising halloysite, hollow nanotubular inorganic structures, and/or tubular inorganic nanomaterials in an amount sufficient for decreasing migration of materials from the composite.

24. The method of claim 23, wherein the method includes:
dispensing the composite onto a surface of a device for managing thermal and/or electromagnetic properties of the device and/or for managing thermal and/or electromagnetic properties of a system including the device; and/or
removing a release liner from the composite, and positioning the composite onto a surface of a device for managing thermal and/or electromagnetic properties of the device and/or for managing thermal and/or electromagnetic properties of a system including the device.
